(19) United States
(12) Patent Application Publication
(10) Pub. No.: US 2025/0167755 A1
(43) Pub. Date: May 22, 2025

(54) Bulk Acoustic Wave Resonator and Preparation Method Thereof

(71) Applicant: Wuhan MEMSonics Technologies Co., Ltd., Wuhan (CN)

(72) Inventors: Zhipeng DING, Wuhan (CN); Qin REN, Wuhan (CN); Ying XIE, Wuhan (CN); Chao GU, Wuhan (CN); Yan LIU, Wuhan (CN); Dawdon CHEAM, Singapore (SG); Yadong XIE, Wuhan (CN); Chengliang SUN, Wuhan (CN); Bowoon SOON, Singapore (SG)

(21) Appl. No.: 18/755,478

(22) Filed: Jun. 26, 2024

(30) Foreign Application Priority Data
Nov. 21, 2023 (CN) 202311569828.4

(51) Int. Cl. H03H 9/02; H03H 3/02; H03H 9/17

(52) U.S. Cl. CPC H03H 9/02086; H03H 3/02; H03H 9/173; H03H 2003/021

(57) ABSTRACT

The present application discloses a bulk acoustic wave resonator and a preparation method thereof. The bulk acoustic wave resonator includes: a substrate, a transducer stacking structure, and a protective layer; the transducer stacking structure is located on one side of the substrate; a cavity is arranged in the substrate; the cavity penetrates through a portion of the substrate; a release channel is arranged in the transducer stacking structure; the release channel penetrates through the transducer stacking structure and is communicated to the cavity; the protective layer is arranged on a surface of one side of the transducer stacking structure away from the substrate; and the protective layer includes a waterproof material.

### CROSS-REFERENCE TO RELATED APPLICATION

This application is filed based upon and claims priority to Chinese Patent Application No. CN202311569828.4, filed on Nov. 21, 2023 the contents of which are hereby incorporated by reference in its entirety.

### TECHNICAL FIELD

The present application relates to the technical field of resonators, and in particular, to a bulk acoustic wave resonator and a preparation method thereof.

### BACKGROUND

A bulk acoustic wave resonator includes an acoustic reflection structure, two electrodes, and a piezoelectric layer that is located between the two electrodes and is referred to as piezoelectric excitation. Sometimes, the two electrodes are also referred to as excitation electrodes having a function of causing mechanical oscillations in all layers of the resonator.

Since lateral dimensions of most bulk acoustic wave resonators are in a micrometer range, and thicknesses of most thin films are in a nanometer range, the bulk acoustic wave resonators are highly sensitive to external environments. Water molecules and gases in the air can interact with a surface of the device, leading to the problems of a decrease in the performance and a decrease in the reliability.

In the existing technology, a passivation layer is usually deposited on an upper surface of the bulk acoustic wave resonator for protection. A material of a traditional passivation layer is generally an aluminum nitride or scandium-doped aluminum nitride thin film. Although this material can provide certain protection for the device, it is difficult for this material to block the interference of water vapor for a long time in a high-temperature environment, which leads to easy deformation of the electrodes and a piezoelectric material, resulting in the problems of a decrease in the performance of the bulk acoustic wave resonator and a frequency shift.

### SUMMARY

The present application provides a bulk acoustic wave resonator and a preparation method thereof.

According to one aspect of the present application, a bulk acoustic wave resonator is provided, including a substrate, a transducer stacking structure, and a protective layer; the transducer stacking structure is located on one side of the substrate;
a cavity is arranged in the substrate, and the cavity penetrates through a portion of the substrate;
a release channel is arranged in the transducer stacking structure, and the release channel penetrates through the transducer stacking structure and is communicated to the cavity;
the protective layer is arranged on a surface of one side of the transducer stacking structure away from the substrate; and the protective layer includes a waterproof material.

In some embodiments, the bulk acoustic wave resonator further includes a protective wall;
the passivation layer is located between the protective layer and the transducer stacking structure, and the passivation layer covers the transducer stacking structure; and
a density of the protective layer is greater than a density of the passivation layer.

In some embodiments, the protective layer is further arranged on an inner wall of the release channel and an inner wall of the cavity.

In some embodiments, the protective layer includes one or more of an inorganic oxide material, a metal oxide material, and a nitride material.

In some embodiments, the transducer stacking structure includes a bottom electrode layer, a piezoelectric layer, and a top electrode layer which are stacked;
the bulk acoustic wave resonator further includes a first electrode plate and a second electrode plate;
the first electrode plate is connected to the piezoelectric layer and the bottom electrode layer through the protective layer; and the second electrode plate is connected to the top electrode layer through the protective layer.

In some embodiments, the substrate includes a bottom-layer substrate, a middle insulation layer, and a top-layer substrate; the top-layer substrate is located on one side close to the transducer stacking structure;
the cavity penetrates through the top-layer substrate;
the bulk acoustic wave resonator further includes a protective wall;
the protective wall covers a side wall of the cavity; and the protective wall is located between the protective layer and the side wall of the cavity.

In some embodiments, the bulk acoustic wave resonator further includes a seed layer;
the seed layer is located between the substrate and transducer stacking structure; and
the seed layer covers the substrate.

According to another aspect of the present application, a preparation method of a bulk acoustic wave resonator, including:
a substrate is provided;
a transducer stacking structure is grown on one side of the substrate;
the transducer stacking structure is etched to form a release channel, and corrosive gas is introduced into the release channel to corrode the substrate and to form a cavity in the substrate; and
a layer of protective layer is deposited on one side of the transducer stacking structure away from the substrate, so that the protective layer is arranged on a surface of the side of the transducer stacking structure away from the substrate,
wherein the protective layer includes a waterproof material.

In some embodiments, a layer of protective layer is deposited on one side of the transducer stacking structure away from the substrate, which includes:
the layer of protective layer is deposited on the side of the transducer stacking structure away from the substrate by using an atomic layer deposition technology.

In some embodiments, a transducer stacking structure is grown on one side of the substrate, which includes:
a bottom electrode layer and a piezoelectric layer are grown in sequence on one side of the protective layer away from the substrate, and the piezoelectric layer is patterned to form a groove that penetrates through the piezoelectric layer;
a top electrode layer is grown on one side of the piezoelectric layer away from the substrate; and
an electrode plate layer is grown on one side of the top electrode layer away from the substrate, and the electrode plate layer is patterned to form a first electrode plate and a second electrode plate.

It should be understood that the content described in the summary section is not intended to identify the key or important features of the embodiments of the present application, and is not intended to limit the scope of the present application. Other features of the present application will be easily understood through the following specification.

### BRIEF DESCRIPTION OF THE DRAWINGS

For clearer descriptions of the technical solutions according to the embodiments of the present application, the drawings required to be used in the description of the embodiments are briefly introduced below. It is obvious that the drawings in the description below are only some embodiments of the present application, and it is obvious for those skilled in the art that other drawings can be acquired according to the drawings without creative efforts.

FIG. 1 is a schematic structural diagram of a first bulk acoustic wave resonator according to an embodiment of present application;

FIG. 2 is a schematic structural diagram of a second bulk acoustic wave resonator according to an embodiment of present application;

FIG. 3 is a schematic structural diagram of a third bulk acoustic wave resonator according to an embodiment of present application;

FIG. 4 is a schematic structural diagram of a fourth bulk acoustic wave resonator according to an embodiment of present application;

FIG. 5 is a flowchart of a preparation method of a first bulk acoustic wave resonator according to an embodiment of the present application;

FIG. 6 is a schematic diagram of a preparation process of a first bulk acoustic wave resonator according to an embodiment of present application;

FIG. 7 is a flowchart of a preparation method of a first bulk acoustic wave resonator according to an embodiment of the present application;

FIG. 8 is a schematic diagram of a preparation process of a second bulk acoustic wave resonator according to an embodiment of present application;

FIG. 9 is a flowchart of a preparation method of a third bulk acoustic wave resonator according to an embodiment of the present application;

FIG. 10 is a schematic diagram of a preparation process of a third bulk acoustic wave resonator according to an embodiment of present application;

FIG. 11 is a flowchart of a preparation method of a fourth bulk acoustic wave resonator according to an embodiment of the present application;

FIG. 12(a) and FIG. 12(b) are schematic diagrams of a preparation process of a fourth bulk acoustic wave resonator according to an embodiment of present application;

FIG. 13 is a flowchart of a preparation method of a fifth bulk acoustic wave resonator according to an embodiment of the present application;

FIG. 14(a) and FIG. 14(b) are schematic diagrams of a preparation process of a fifth bulk acoustic wave resonator according to an embodiment of present application;

FIG. 15 is a schematic structural diagram of a bulk acoustic wave filter according to an embodiment of present application;

FIG. 16 shows test results of a ubias highly accelerated stress test on a bulk acoustic wave filter in the existing technology;

FIG. 17 is a response diagram of a test broad band of a ubias highly accelerated stress test on a bulk acoustic wave filter according to an embodiment of present application; and

FIG. 18 is a response diagram of a test narrow band of a ubias highly accelerated stress test on a bulk acoustic wave filter according to an embodiment of present application.

### DETAILED DESCRIPTION OF THE EMBODIMENTS

In order to make a person skilled in the art to better understand the solutions of the present application, the technical solutions in the embodiments of the present application are clearly and completely described below with reference to the accompanying drawings in the embodiments of the present application. Apparently, the described embodiments are merely some rather than all of the embodiments of the present application. All other embodiments obtained by a person of ordinary skill in the art based on the embodiments of the present application without making creative efforts shall fall within the protection scope of the present application.

It should be noted that the terms “first”, “second”, etc. in the specification and claims of the present application and the above accompanying drawings are defined to distinguish similar objects, and do not have to be used to describe a specific order or sequence. It should be understood that such used data is interchangeable where appropriate, so that the embodiments of the present application described here can be implemented in an order other than those illustrated or described here. In addition, the terms “include” and “have”, as well as any variations thereof, are intended to cover non-exclusive inclusion. For example, a process, method, system, product, or equipment that includes a series of steps or units does not need to be limited to those clearly listed steps or units, but may include other steps or units not clearly listed or inherent to these processes, methods, products, or equipment.

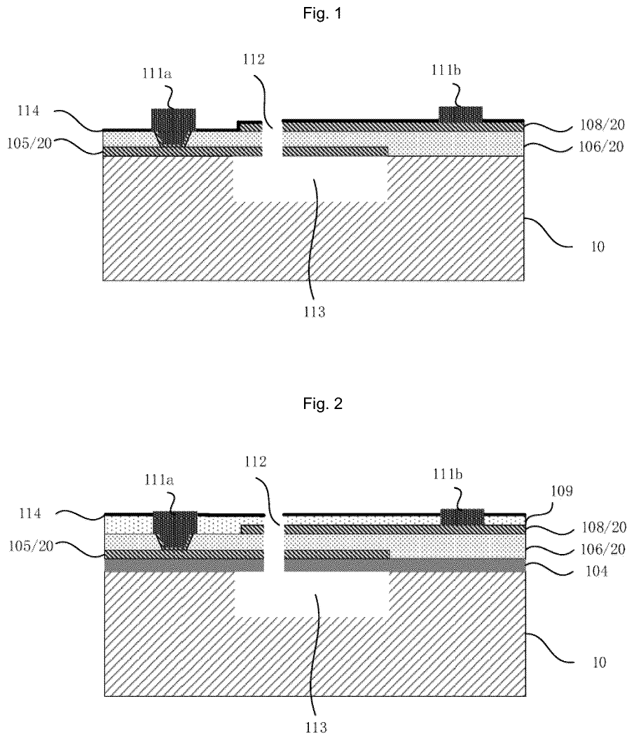

FIG. 1 is a schematic structural diagram of a first bulk acoustic wave resonator according to an embodiment of present application. As shown in FIG. 1, the bulk acoustic wave resonator includes:
a substrate 10, a transducer stacking structure 20, and a protective layer 114. The transducer stacking structure 20 is located on one side of the substrate 10;
a cavity 113 is arranged in the substrate 10, and the cavity 113 penetrates through a portion of the substrate 10;
a release channel 112 is arranged in the transducer stacking structure 20, and the release channel 112 penetrates through the transducer stacking structure 20 and is communicated to the cavity 113;
the protective layer 114 is arranged on a surface of one side of the transducer stacking structure 20 away from the substrate 10; and the protective layer 114 includes a waterproof material.

In the bulk acoustic wave resonator, the transducer stacking structure 20 can include excitation electrodes and a piezoelectric layer arranged between the excitation electrodes. The transducer stacking structure 20 is arranged on one side of the substrate 10, so that mechanical oscillations of all layers of the bulk acoustic wave resonator are caused through the excitation electrodes. In addition, the transducer stacking structure 20 also includes the release channel 112, and the release channel 112 penetrates through the transducer stacking structure 20. It can be understood that the transducer stacking structure 20 may include a plurality of release channels 112, and the release channels 112 are configured to introduce corrosive gas to one side of the substrate 10. The corrosive gas can be simultaneously introduced into the plurality of release channels 112 to increase the formation rate of the cavity 113.

In the existing technology, lateral dimensions of most bulk acoustic wave resonators are in a micrometer range, and thicknesses of all layers of thin films are about in a nanometer range, a bulk acoustic wave filter is highly sensitive to external environments. Water molecules and gases in the air can interact with the excitation electrodes, the piezoelectric layer, or other structures in the bulk acoustic wave resonator, leading to the problems of a decrease in the performance and a decrease in the reliability. Therefore, in this embodiment of the present application, the protective layer 114 is arranged in the bulk acoustic wave resonator. The protective layer 114 is arranged on a surface of one side of the transducer stacking structure 20 away from the substrate 10. The protective layer 114 covers the transducer stacking structure 20 and is made of a waterproof material, such as various waterproof thin films. In this way, the protective layer 114 can isolate the excitation electrodes and the piezoelectric layer in the bulk acoustic wave resonator from water vapor in the air, which avoids the influence of the water vapor on the performance of the bulk acoustic wave resonator, and achieves in-situ protection of the bulk acoustic wave resonator.

In some embodiments, the protective layer 114 includes one or more of an inorganic oxide material, a metal oxide material, and a nitride material. The inorganic oxide material can be SiO₂; the metal oxide material can be Al₂O₃, Zr₂O₃, TiO₂, or the like; the nitride material can be AlN, SiN, or the like. The protective layer may also include various composite thin films of the above materials, to play a role in isolating the water vapor.

According to the technical solution in this embodiment of the present application, the protective layer with the waterproof material is arranged in the bulk acoustic wave resonator, and the protective layer is arranged on the surface of the transducer stacking structure to isolate the excitation electrodes and the piezoelectric layer from the water vapor in the air, thus protecting the transducer stacking structure from being affected by the water vapor and improving the reliability of the bulk acoustic wave resonator.

In some embodiments, continuing to refer to FIG. 1, the transducer stacking structure 20 includes a bottom electrode layer 105, a piezoelectric layer 106, and a top electrode layer 108 which are stacked;
the bulk acoustic wave resonator further includes a first electrode plate 111a and a second electrode plate 111b;
the first electrode plate 111a is connected to the piezoelectric layer 106 and the bottom electrode layer 105 through the protective layer 114; and the second electrode plate 111b is connected to the top electrode layer 108 through the protective layer 114.

The bottom electrode layer 105 and the top electrode layer 108 are the excitation electrodes, and the piezoelectric layer 106 is arranged between the two excitation electrodes. The bottom electrode layer 105 and the top electrode layer 108 serve as the excitation electrodes to cause the mechanical oscillations between all the layers of the bulk acoustic wave resonator. The piezoelectric layer 106 achieves the effect of piezoelectric excitation. The release channel 112 is communicated to the cavity 113 through the bottom electrode layer 105, the piezoelectric layer 106, and the top electrode layer 108, so as to achieve the preparation of the cavity 113.

The first electrode plate 111a is configured to: lead out the bottom electrode layer 105 and connect the bottom electrode layer 105 to an external circuit, and the second electrode plate 111b is configured to lead out the top electrode layer 108 and connect the top electrode layer 108 to the external circuit. The first electrode plate 111a is connected to the bottom electrode layer 105 through the piezoelectric layer 106, so that the external circuit can be connected to the bottom electrode layer 105 by being connected to the first electrode plate 111a; and the second electrode plate 111b is connected to the top electrode layer 108, so that the external circuit can be connected to the top electrode layer 108 by being connected to the second electrode plate 111b.

In some embodiments, the piezoelectric layer 106 can be etched before the preparation of the protective layer 114, so as to expose the bottom electrode layer 105 and forming a groove; an electrode plate layer is deposited; and the electrode plate layer is patterned to form the first electrode plate 111a and the second electrode plate 111b.

According to the technical solution in this embodiment of the present application, the first electrode plate and the second electrode plate are arranged in the bulk acoustic wave resonator, the first electrode plate is connected to the bottom electrode layer, and the second electrode plate is connected to the top electrode layer, so that the connection between the bulk acoustic wave resonator and the external circuit.

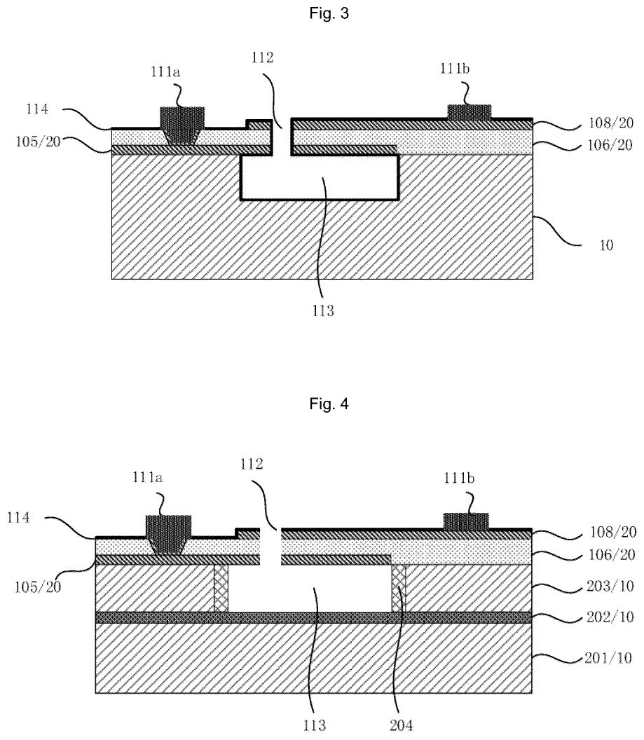

In some embodiments, FIG. 2 is a schematic structural diagram of a second bulk acoustic wave resonator according to an embodiment of present application. As shown in FIG. 2, the bulk acoustic wave resonator further includes a passivation layer 109;
the passivation layer 109 is located between the protective layer 114 and the transducer stacking structure 20, and the passivation layer 109 covers the transducer stacking structure 20; and
a density of the protective layer 114 is greater than a density of the passivation layer 109.

The passivation layer 109 is arranged between the protective layer 114 and the transducer stacking structure 20, and covers the transducer stacking structure 20. On the one hand, the passivation layer 109 can further protect the transducer stacking structure 20, and on the other hand, the passivation layer 109 can also play a role in frequency modulation. By adjusting the thickness of the passivation layer 109, the frequency of the bulk acoustic wave resonator can be adjusted to achieve a target frequency.

In some embodiments, the passivation layer 109 is often formed by using chemical vapor deposition, and a material of the passivation layer can be an aluminum nitride or scandium-doped aluminum nitride thin film. The protective layer 114 is often formed by using atomic layer deposition. When the protective layer 114 also uses the aluminum nitride material, different deposition methods make a deposition density of the protective layer 114 greater than that of the passivation layer 109. Due to the larger deposition density, the protective layer 114 can better isolate the water vapor and high temperature in the air and achieve a better protection effect.

It can be understood that since the passivation layer 109 also has a certain frequency modulation effect, the passivation layer needs to have a thickness that is suitable for a compensation frequency of the bulk acoustic wave resonator. In addition, the protective layer 114 in this embodiment of the present application may also use other waterproof materials, and this embodiment of the present application does not impose any limitation on this.

According to the technical solution in this embodiment of the present application, the passivation layer is arranged between the protective layer and the transducer stacking structure, so that the passivation layer can not only protect the transducer stacking structure, but also play a role in frequency modulation, so that the bulk acoustic wave resonator has double protection by the passivation layer and the protective layer, which further improves the reliability of the bulk acoustic wave resonator.

In some embodiments, FIG. 3 is a schematic structural diagram of a third bulk acoustic wave resonator according to an embodiment of present application. As shown in FIG. 3, the protective layer 114 is also arranged on an inner wall of the release channel 112 and an inner wall of the cavity 113.

Due to the fact that the transducer stacking structure 20 includes the release channel 112 communicated to the cavity 113, when the protective layer 114 is grown by using the atomic layer deposition, reaction gas and particles may reach the cavity 113 through the release channel 112 during the deposition, and the protective layer 114 may be formed on various surfaces of the cavity 113. Therefore, the protective layer 114 covers the inner wall of the release channel 112 to protect the piezoelectric layer 106 on the side wall of the release channel 112 from being interfered by the water vapor, and the reliability of the bulk acoustic wave resonator is improved. Meanwhile, the protective layer 114 covers the inner wall of the cavity 113, which can further ensure that the excitation electrodes at the bottom are free from the influence of the water vapor, and this improves the reliability of the bulk acoustic wave resonator.

In some embodiments, FIG. 4 is a schematic structural diagram of a fourth bulk acoustic wave resonator according to an embodiment of the present application. As shown in FIG. 4, a substrate 10 includes a bottom-layer substrate 201, a middle insulation layer 202, and a top-layer substrate 203; the top-layer substrate 203 is located on one side close to a transducer stacking structure 20;
a cavity 113 penetrates through the top-layer substrate 203;
the bulk acoustic wave resonator further includes a protective wall 204;
the protective wall 204 covers a side wall of the cavity 113; and the protective wall 204 is located between a protective layer 114 and the side wall of the cavity 113.

The substrate 10 can be a Silicon-On-Insulator (SOI) substrate on an insulating substrate. The SOI substrate includes a bottom-layer substrate 201, a middle insulation layer 202, and a top-layer substrate 203. The protective wall 204 achieves an effect of limiting a range of the cavity 113. The protective wall 204 is arranged on the side wall of the cavity 113, which can isolate the substrate 10 from the cavity 113. It should be noted that the substrate 10 is not limited to the above-mentioned types. For example, the substrate 10 can also be a silicon wafer or a silicon carbide wafer. In addition, the substrate 10 can be set to include both a silicon layer and a silicon carbide layer. For example, the substrate 10 includes a bottom-layer substrate 201, a middle insulation layer 202, and a top-layer substrate 203. The bottom-layer substrate 201 can be the silicon layer, and the top-layer substrate 203 can be the silicon nitride layer. This embodiment does not impose a specific limitation on this.

Specifically, during the preparation, corrosive gas enters the substrate 10 through the release channel 112. By the restriction of the side wall of the protective wall 204 and the middle insulation layer 202, the limitation range of the cavity 113 is fixed, thus forming the structure of the cavity 113 that penetrates through the top-layer structure 203.

In this embodiment of the present application, the use of SOI substrate can limit the range of the cavity on the one hand, and on the other hand, the SOI substrate can play a role in isolating current and reducing parasitic capacitance. Meanwhile, in this embodiment of the present application, the protective wall is also provided. When the corrosive gas enters the substrate through the release channel, under the action of the protective wall, the problem that the corrosive gas is excessively released on the side wall of the substrate can be further avoided.

In an actual process flow, one side of the substrate 10 is etched first to form a positioning groove. The protective wall 204 is further deposited on a surface of the substrate 10 and in the positioning groove. Later, the protective wall 204 is ground to expose the surface of the substrate 10, so that the protective wall 204 only fills the positioning groove. It can be understood that the positioning groove is a structure that limits the range of the cavity 113 before the corrosive gas corrodes the substrate 10, and a region surrounded by the positioning groove is a region of the cavity 113.

In some embodiments, as shown in FIG. 2, the bulk acoustic wave resonator further includes a seed layer 104;
the seed layer 104 is located between the substrate 10 and transducer stacking structure 20; and the seed layer 104 covers the substrate 10.

Specifically, the seed layer 104 can be a material that is matched with a lattice of the piezoelectric layer 106 in the transducer stacking structure 20, such as an aluminum nitride material or a scandium aluminum nitride material, so that the piezoelectric layer 106 in the transducer stacking structure 20 has a better crystal axis growth orientation later, which improves the quality of deposition of the piezoelectric layer 106, thereby increasing a Q value of the bulk acoustic wave resonator. For example, in the process of preparing the seed layer 104, a high-temperature Physical Vapor Deposition (PVD) or Metal Organic Chemical Vapor Deposition (MOCVD) can be used to enable an AlN thin film to achieve a good c-axis orientation, which is beneficial for preferred orientation growth of the c-axis of the piezoelectric layer 106 in the transducer stacking structure 20 layer, thus improving the quality of deposition of the piezoelectric layer 106 and increasing the Q value of the bulk acoustic wave resonator.

According to the technical solution of this embodiment of the present application, the seed layer is arranged between the substrate and the transducer stacking structure. On the one hand, the seed layer is located between the cavity and the transducer stacking structure, which can induce the growth of the bottom electrode layer. On the other hand, the seed layer is matched with the lattice of the piezoelectric layer, which can further improve the quality of deposition of the piezoelectric layer, thereby increasing the Q value of the bulk acoustic wave resonator.

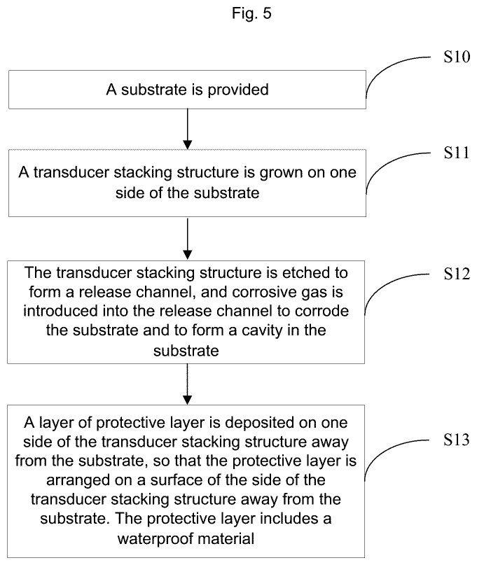

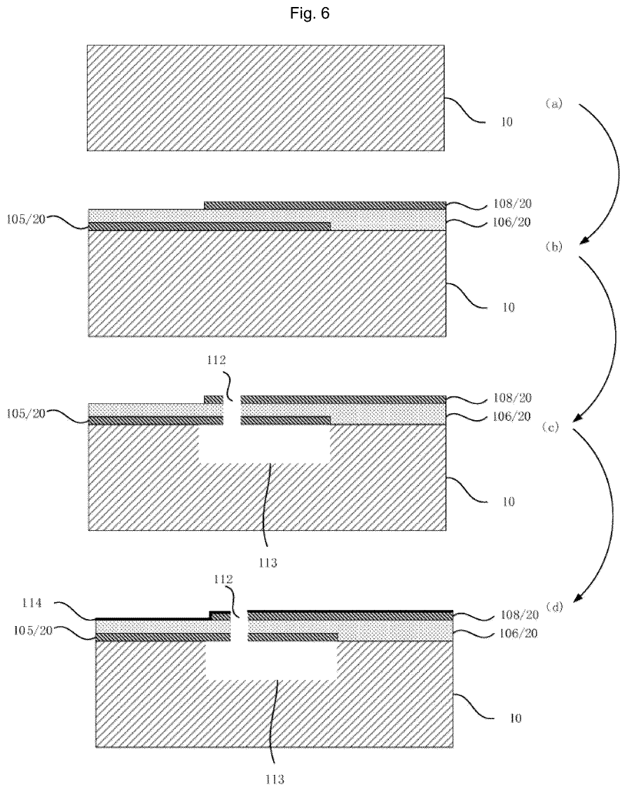

FIG. 5 is a flowchart of a preparation method of a first bulk acoustic wave resonator according to an embodiment of the present application, and FIG. 6 is a schematic diagram of a preparation process of a first bulk acoustic wave resonator according to an embodiment of present application. With reference to FIG. 5 and FIG. 6, this embodiment of the present application further provides a preparation of a bulk acoustic wave resonator. The preparation method includes:
S10. A substrate is provided.

The substrate 10 may be a Si substrate, a SiC substrate, a sapphire substrate, or a SOI substrate.

Step S10 corresponds to step a in FIG. 6. A reference is made to step a.

When the substrate 10 is the Si substrate, the SiC substrate, and the sapphire substrate, for subsequent formation of a cavity 113, the substrate 10 is etched in advance to form a third groove. A range of the third groove is a range of the cavity 113. A sacrificial layer is further deposited in the third groove, and the sacrificial layer is ground by using a chemical mechanical polishing method to expose a surface of the substrate 10, so that the sacrificial layer only fills the third groove to ensure the subsequent formation of the cavity 113 (not shown in the figure).

Specifically, when the substrate 10 is the SOI substrate, as the SOI substrate includes a bottom-layer substrate, a middle insulation layer, and a top-layer substrate, a protective wall can be further arranged in the substrate 10. Firstly, the substrate 10 is etched to form a positioning groove, and a region surrounded by the positioning groove is a range of the cavity. Further, a protective wall is deposited in the positioning groove, and the protective wall is ground by using a chemical mechanical polishing method to expose a surface of the substrate 10, so that the protective wall only fills the positioning groove. This protective wall does not react with corrosive gases, so that the protective wall and the middle insulation layer can achieve an effect of limiting the cavity (not shown in the figure).
S11. A transducer stacking structure is grown on one side of the substrate.

Step S11 corresponds to step b in FIG. 6. A reference is made to step b. Since the transducer stacking structure 20 includes a bottom electrode layer 105, a piezoelectric layer 106, and a top electrode layer 108, a transducer stacking structure 20 is grown on one side of the substrate 10, which includes: The bottom electrode layer 105, the piezoelectric layer 106, and the top electrode layer 108 are grown on one side of the substrate 10 in sequence.
S12. The transducer stacking structure is etched to form a release channel, and corrosive gas is introduced into the release channel to corrode the substrate and to form a cavity in the substrate.

Step S12 corresponds to step c in FIG. 6. A reference is made to step c. The transducer stacking structure 20 is etched to form a release channel 112. There may include a plurality of release channels 112, so that the release channels 112 penetrate through the transducer stacking structure 20, so that the corrosive gas entering through the release channels 112 can be in full contact with the substrate 10. It can be understood that a range of the release channel 112 needs to be within the corresponding range of the cavity 113, that is, the corrosive gas passing through the release channel 112 needs to enter the range positioned by the third groove or a range positioned by a positioning groove to ensure the formation of the cavity 113.

The corrosive gas is introduced into the release channel 112, and the corrosive gas reacts with the top-layer substrate 203 or a sacrificial layer to form the cavity 113.
S13. A layer of protective layer is deposited on one side of the transducer stacking structure away from the substrate, so that the protective layer is arranged on a surface of the side of the transducer stacking structure away from the substrate. The protective layer includes a waterproof material.

Step S13 corresponds to step d in FIG. 6. A reference is made to step d. A layer of protective layer 14 is deposited on one side of the transducer stacking structure 20 away from the substrate 10, so that the protective layer 114 covers a surface of one side of the transducer stacking structure 20 away from the substrate 10, that is, covers the top electrode layer 108 and the piezoelectric layer 106 in transducer stacking structure 20. The protective layer 114 is made of the waterproof material, such as various waterproof thin films. In this way, the protective layer 114 can isolate excitation electrodes and the piezoelectric layer 106 in the bulk acoustic wave resonator from water vapor in the air, which avoids the influence of the water vapor on the performance of the bulk acoustic wave resonator, and achieves in-situ protection of the bulk acoustic wave resonator.

According to the technical solution in this embodiment of the present application, the protective layer with the waterproof material is arranged in the bulk acoustic wave resonator, and the protective layer is arranged on the surface of the transducer stacking structure to isolate the excitation electrodes and the piezoelectric layer from the water vapor in the air, thus protecting the transducer stacking structure from being affected by the water vapor and improving the reliability of the bulk acoustic wave resonator.

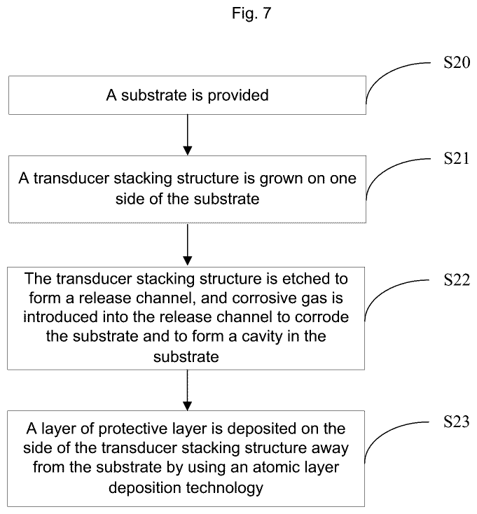

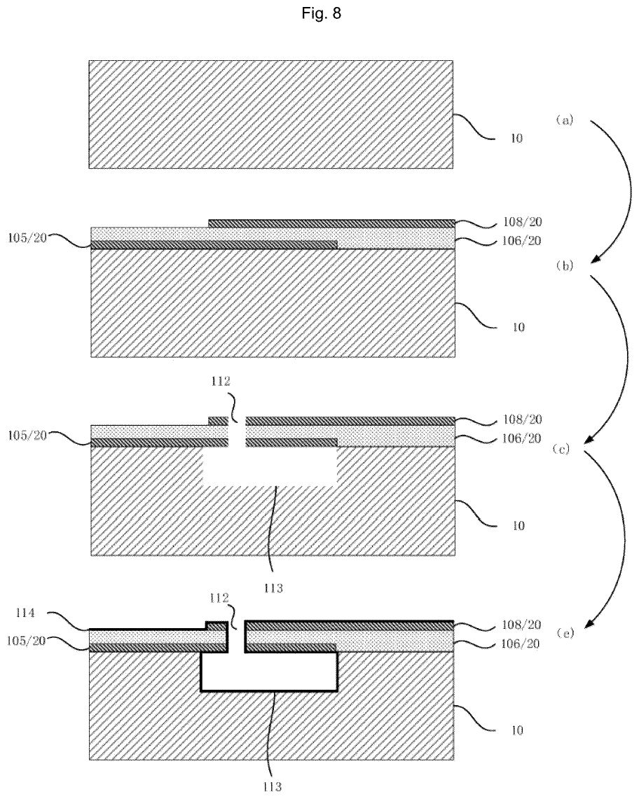

On the basis of the above embodiments, FIG. 7 is a flowchart of a preparation method of a second bulk acoustic wave resonator according to an embodiment of the present application FIG. 8 is a schematic diagram of a preparation process of a second bulk acoustic wave resonator according to an embodiment of present application. With reference to FIG. 7 and FIG. 8, the preparation method includes:
S20. A substrate is provided.
S21. A transducer stacking structure is grown on one side of the substrate.
S22. The transducer stacking structure is etched to form a release channel, and corrosive gas is introduced into the release channel to corrode the substrate and to form a cavity in the substrate.
S23. A layer of protective layer is deposited on the side of the transducer stacking structure away from the substrate by using an atomic layer deposition technology.

Step S23 corresponds to step e in FIG. 8. A reference is made to step e. The atomic layer deposition technology can be a method for coating a surface of the transducer stacking structure 20 with a substance layer by layer in the form of a single atom film layer. Due to the fact that the transducer stacking structure 20 includes the release channel 112 and the cavity 113 communicated to the release channel 112, when the protective layer 114 is grown by using the atomic layer deposition, reaction gas and particles may reach the cavity 113 through the release channel 112 during the deposition, and the protective layer 114 may be formed on various surfaces of the cavity 113. Therefore, the protective layer 114 covers the inner wall of the release channel 112 to protect the piezoelectric layer 106 on the side wall of the release channel 112 from being interfered by the water vapor, and the reliability of the bulk acoustic wave resonator is improved. Meanwhile, the protective layer 114 covers the inner wall of the cavity 113, which can further ensure that the excitation electrodes at the bottom are free from the influence of the water vapor, and this improves the reliability of the bulk acoustic wave resonator.

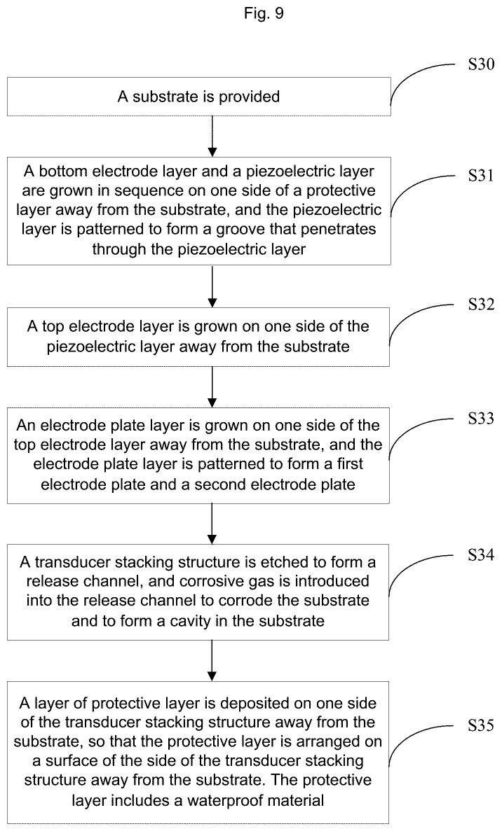

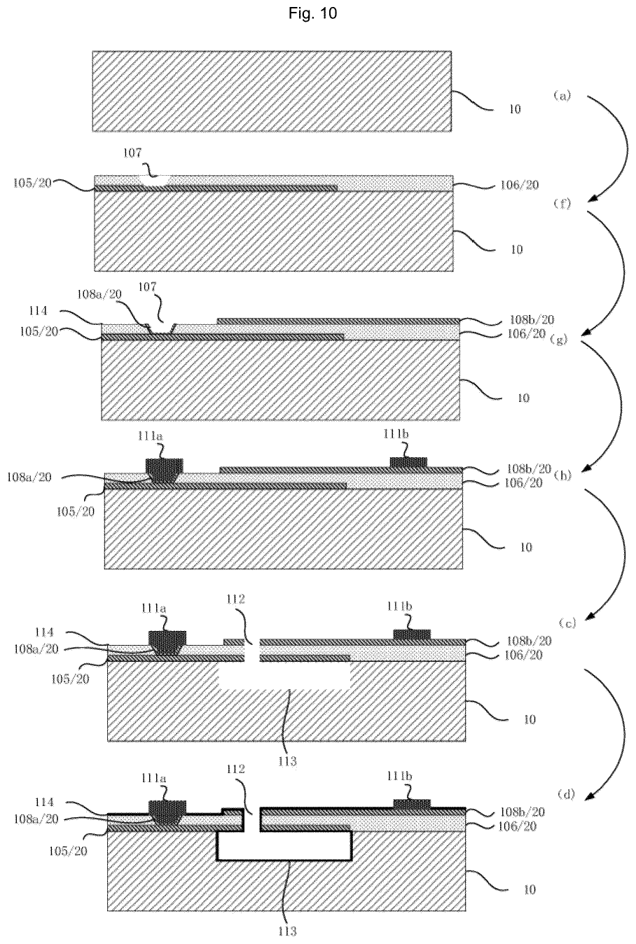

On the basis of the above embodiments, FIG. 9 is a flowchart of a preparation method of a third bulk acoustic wave resonator according to an embodiment of the present application FIG. 10 is a schematic diagram of a preparation process of a third bulk acoustic wave resonator according to an embodiment of present application. With reference to FIG. 9 and FIG. 10, the preparation method includes:
S30. A substrate is provided.
S31. A bottom electrode layer and a piezoelectric layer are grown in sequence on one side of a protective layer away from the substrate, and the piezoelectric layer is patterned to form a groove that penetrates through the piezoelectric layer.

Step S31 corresponds to step f in FIG. 10. A reference is made to step f. A first electrode plate 111a needs to be connected to the bottom electrode layer 105, so that the piezoelectric layer 106 needs to be etched to form the groove 107. The groove 107 is configured to lead out the bottom electrode layer 105 according to the first electrode plate 111a.
S32. A top electrode layer is grown on one side of the piezoelectric layer away from the substrate.

Step S32 corresponds to step g in FIG. 10. A reference is made to step g. The top electrode layer 108 is grown and patterned on one side of the piezoelectric layer 106 away from the substrate 10, so that the top electrode layer 108 is divided into two parts. One part is on a surface of the piezoelectric layer 106 (as shown in 108b in FIG. 10), and the other part is configured to lead out the bottom electrode layer 105 in the groove (as shown in 108a in FIG. 10). As the piezoelectric layer 106 is an insulation layer, a portion of the top electrode layer 108 is connected to the bottom electrode layer 105 in the groove, which can lead out the bottom electrode layer 105 for subsequent connection between the bottom electrode layer 105 and an external circuit.
S33. An electrode plate layer is grown on one side of the top electrode layer away from the substrate, and the electrode plate layer is patterned to form a first electrode plate and a second electrode plate.

Step S33 corresponds to step h in FIG. 10. A reference is made to step h. The electrode plate layer is grown on one side of the transducer stacking structure 20 away from the substrate 10, so that the electrode plate layer covers the groove on the surface of the top electrode layer 108, and the electrode plate layer is patterned to form the first electrode plate 111a and the second electrode plate 111b. The first electrode plate 111a is connected to the bottom electrode layer 105 through the piezoelectric layer 106, so that the external circuit can be connected to the bottom electrode layer 105 by being connected to the first electrode plate 111a; and the second electrode plate 111b is connected to the top electrode layer 108, so that the external circuit can be connected to the top electrode layer 108 by being connected to the second electrode plate 111b.
S34. A transducer stacking structure is etched to form a release channel, and corrosive gas is introduced into the release channel to corrode the substrate and to form a cavity in the substrate.
S35. A layer of protective layer is deposited on one side of the transducer stacking structure away from the substrate, so that the protective layer is arranged on a surface of the side of the transducer stacking structure away from the substrate. The protective layer includes a waterproof material.

According to the technical solution in this embodiment of the present application, the first electrode plate and the second electrode plate are arranged in the bulk acoustic wave resonator, the first electrode plate is connected to the bottom electrode layer, and the second electrode plate is connected to the top electrode layer, so that the connection between the bulk acoustic wave resonator and the external circuit.

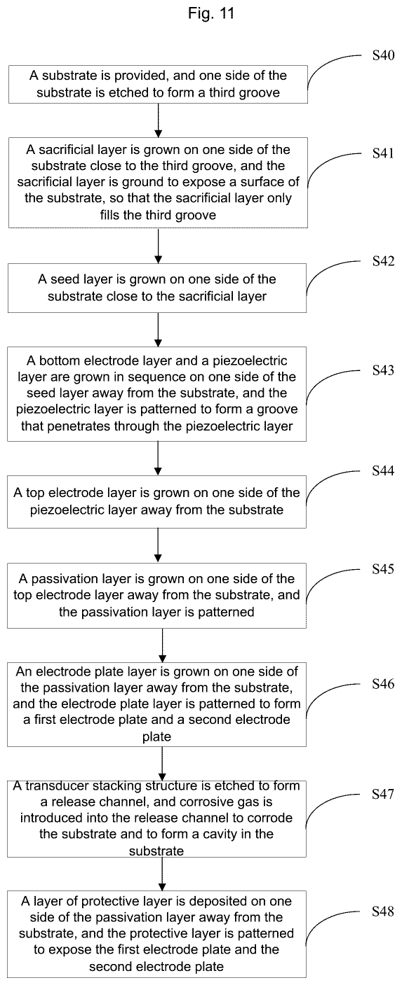

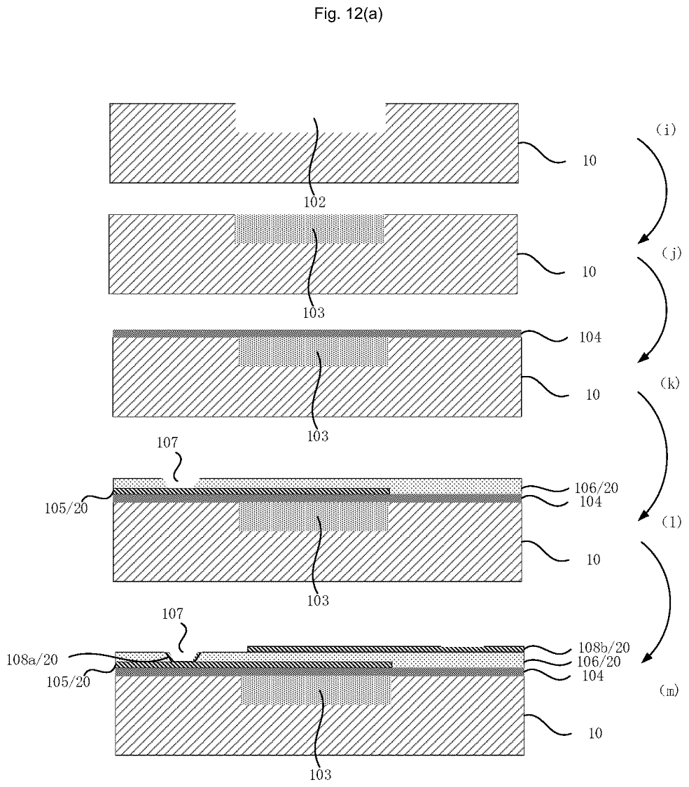

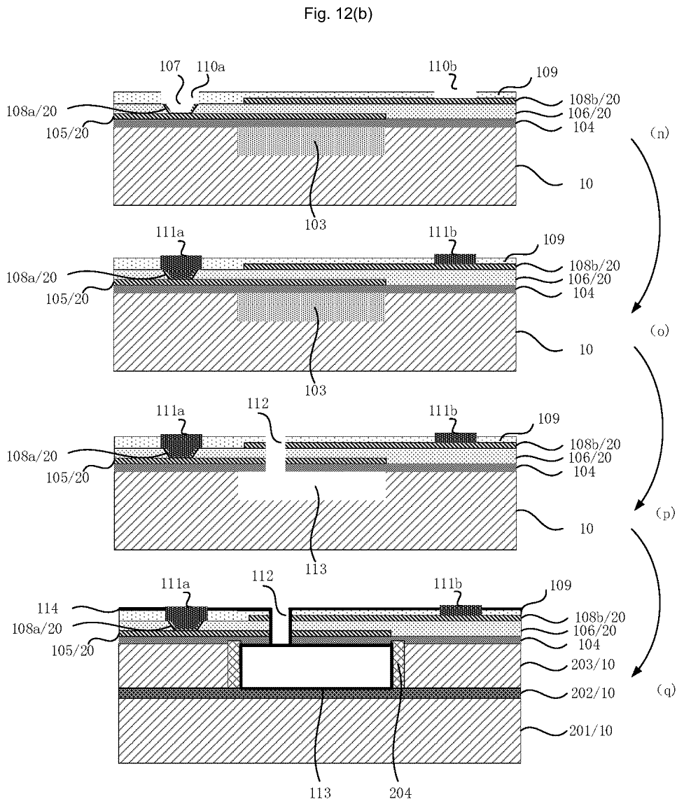

On the basis of the above embodiments, FIG. 11 is a flowchart of a preparation method of a fourth bulk acoustic wave resonator according to an embodiment of the present application FIG. 12(a) and FIG. 12(b) are schematic diagrams of a preparation process of a fourth bulk acoustic wave resonator according to an embodiment of present application. A substrate 10 in the preparation method as shown in FIG. 11 is a Si substrate. The preparation method includes:
S40. A substrate is provided, and one side of the substrate is etched to form a third groove.

Step S40 corresponds to step i in FIG. 12(a). A reference is made to step i. In FIG. 12(a), a substrate 10 is provided, and one side of the substrate 10 is etched to form a third groove 102.
S41. A sacrificial layer is grown on one side of the substrate close to the third groove, and the sacrificial layer is ground to expose a surface of the substrate, so that the sacrificial layer only fills the third groove.

Step S41 corresponds to step j in FIG. 12(a). A reference is made to step j. A sacrificial layer 103 is grown on one side of the substrate 10 close to the third groove 102, and the sacrificial layer is ground to expose a surface of the substrate, so that the sacrificial layer 103 only fills the third groove.
S42. A seed layer is grown on one side of the substrate close to the sacrificial layer.

Step S42 corresponds to step k in FIG. 12(a). A reference is made to step k. 104 in FIG. 12(a) represents a seed layer.
S43. A bottom electrode layer and a piezoelectric layer are grown in sequence on one side of the seed layer away from the substrate, and the piezoelectric layer is patterned to form a groove that penetrates through the piezoelectric layer.

Step S43 corresponds to step l in FIG. 12(a). A reference is made to step l.
S44. A top electrode layer is grown on one side of the piezoelectric layer away from the substrate.

Step S44 corresponds to step m in FIG. 12(a). A reference is made to step m.
S45. A passivation layer is grown on one side of the top electrode layer away from the substrate, and the passivation layer is patterned.

Step S45 corresponds to step n in FIG. 12(b). A reference is made to step n. It can be understood that the purpose of patterning the passivation layer 109 is to expose the bottom electrode layer 105 and the top electrode layer 108. After the patterning, a first opening 110a and a second opening 110b are included for subsequent deposition of an electrode plate layer.
S46. An electrode plate layer is grown on one side of the passivation layer away from the substrate, and the electrode plate layer is patterned to form a first electrode plate and a second electrode plate.

Step S46 corresponds to step o in FIG. 12(b). A reference is made to step o.
S47. A transducer stacking structure is etched to form a release channel, and corrosive gas is introduced into the release channel to corrode the substrate and to form a cavity in the substrate.

Step S47 corresponds to step p in FIG. 12(b). A reference is made to step p.
S48. A layer of protective layer is deposited on one side of the passivation layer away from the substrate, and the protective layer is patterned to expose the first electrode plate and the second electrode plate.

Step S48 corresponds to step q in FIG. 12(b). A reference is made to step q.

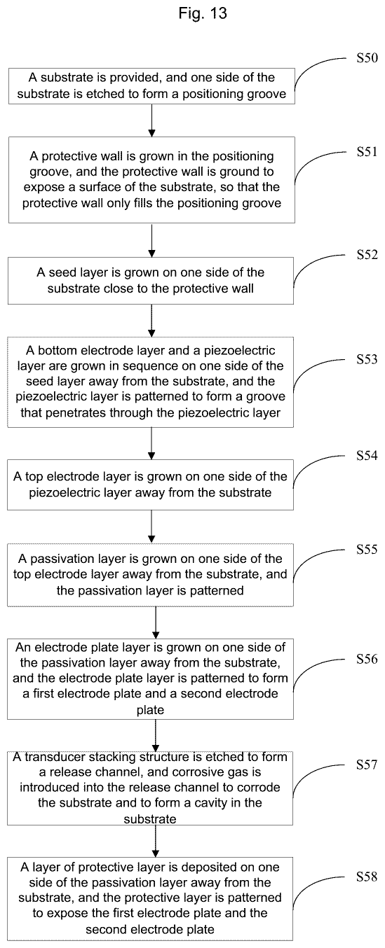

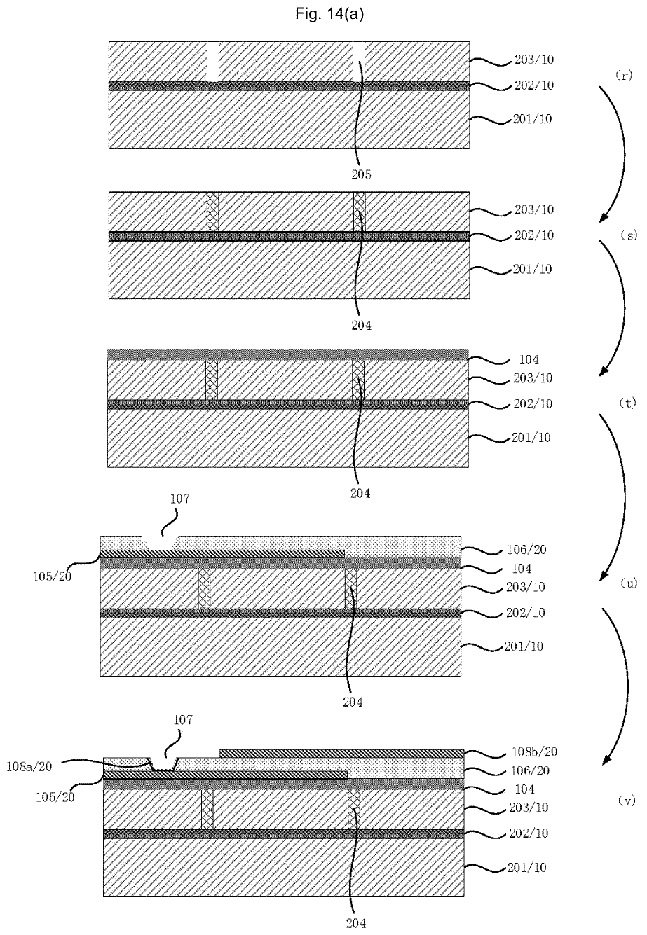

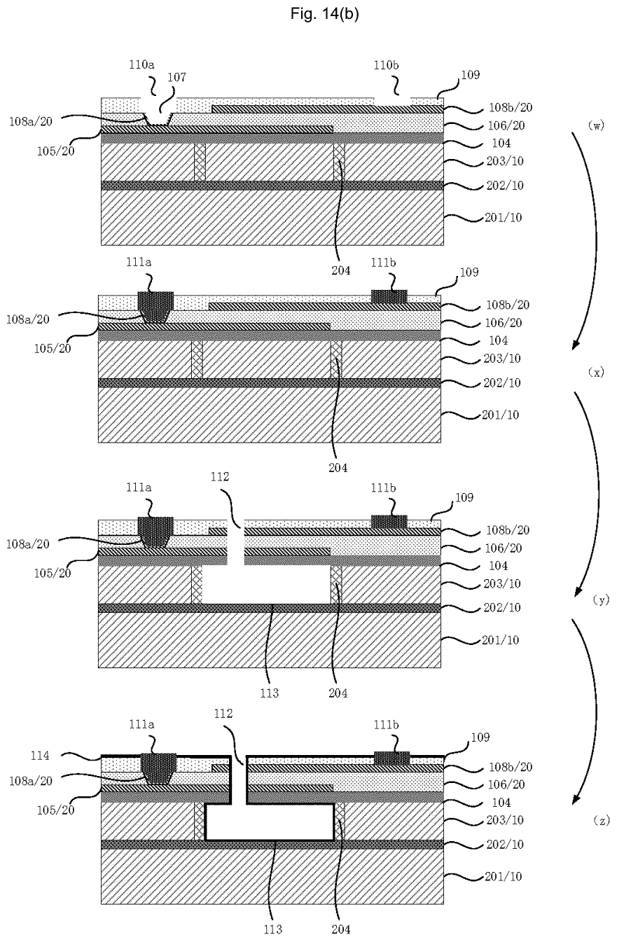

On the basis of the above embodiments, FIG. 13 is a flowchart of a preparation method of a fifth bulk acoustic wave resonator according to an embodiment of the present application FIG. 14(a) and FIG. 14(b) are schematic diagrams of a preparation process of a fifth bulk acoustic wave resonator according to an embodiment of present application. A substrate 10 in the preparation method as shown in FIG. 13 is a SOI substrate. The preparation method includes:
S50. A substrate is provided, and one side of the substrate is etched to form a positioning groove.

Step S50 corresponds to step r in FIG. 14(a). A reference is made to step r. In FIG. 14(a), a substrate 10 is provided, and one side of the substrate 10 is etched to form a positioning groove 205.
S51. A protective wall 204 is grown in the positioning groove, and the protective wall is ground to expose a surface of the substrate, so that the protective wall 204 only fills the positioning groove.

Step S51 corresponds to step s in FIG. 14(a). A reference is made to step s. In FIG. 14(a), the protective wall 204 fills the positioning groove 205 to limit the cavity 113.
S52. A seed layer is grown on one side of the substrate close to the protective wall 204.

Step S52 corresponds to step t in FIG. 14(a). A reference is made to step t. In FIG. 14(a), 104 represents a seed layer.
S53. A bottom electrode layer and a piezoelectric layer are grown in sequence on one side of the seed layer away from the substrate, and the piezoelectric layer is patterned to form a groove that penetrates through the piezoelectric layer.

Step S53 corresponds to step u in FIG. 14(a). A reference is made to step u.
S54. A top electrode layer is grown on one side of the piezoelectric layer away from the substrate.

Step S54 corresponds to step v in FIG. 14(a). A reference is made to step v.
S55. A passivation layer is grown on one side of the top electrode layer away from the substrate, and the passivation layer is patterned.

Step S55 corresponds to step w in FIG. 14(b). A reference is made to step w. It can be understood that the purpose of patterning the passivation layer 109 is to expose the bottom electrode layer 105 and the top electrode layer 108. After the patterning, a first opening 110a and a second opening 110b are included for subsequent deposition of an electrode plate layer.
S56. An electrode plate layer is grown on one side of the passivation layer away from the substrate, and the electrode plate layer is patterned to form a first electrode plate and a second electrode plate.

Step S56 corresponds to step x in FIG. 14(b). A reference is made to step x.
S57. A transducer stacking structure is etched to form a release channel, and corrosive gas is introduced into the release channel to corrode the substrate and to form a cavity in the substrate.

Step S57 corresponds to step y in FIG. 14(b). A reference is made to step y.
S58. A layer of protective layer is deposited on one side of the passivation layer away from the substrate, and the protective layer is patterned to expose the first electrode plate and the second electrode plate.

Step S58 corresponds to step z in FIG. 14(b). A reference is made to step z.

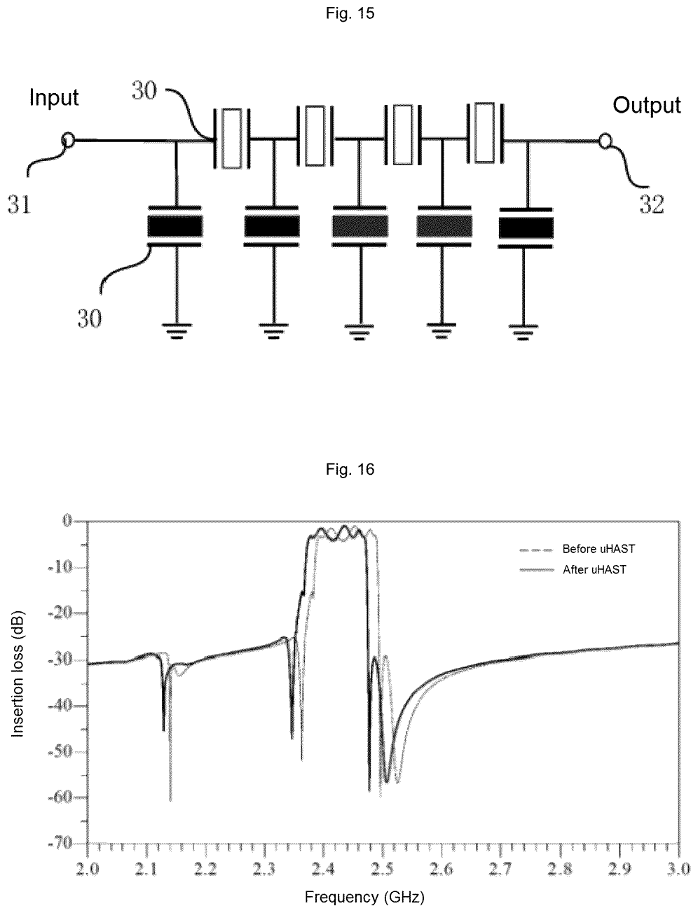

FIG. 15 is a schematic structural diagram of a body sound wave filter according to an embodiment of the present application. This embodiment of the present application further provides a body sound wave filter. The body sound wave filter includes an input port 31, an output port 32, and a plurality of body sound wave resonators 30.

Upper and lower surfaces of each body sound wave resonator 30 are covered with protective layers, so that the body sound wave filter can be prevented from being interfered by water vapor, and the reliability of the body sound wave filter is improved.

FIG. 16 shows test results of a highly accelerated temperature and humidity test on a bulk acoustic wave filter in the existing technology. As shown in FIG. 16, conditions of the ubias Highly Accelerated Stress Test (uHAST) in FIG. 16 include: a temperature of 130° C., a relative humidity of 85%, a pressure of 33.3 psi, and test time of 96 hours. As shown in FIG. 16, although the bottom electrode layer and the top electrode layer of the bulk acoustic wave filter in the existing technology are respectively protected by the passivation layer and the seed layer, the materials commonly used for the passivation layer and the seed layer are aluminum nitride or scandium-doped aluminum nitride thin films, which have low reliability and can hardly block the interference of the water vapor for a long time. As a result, an electrode or piezoelectric material deforms, leading to a frequency shift.

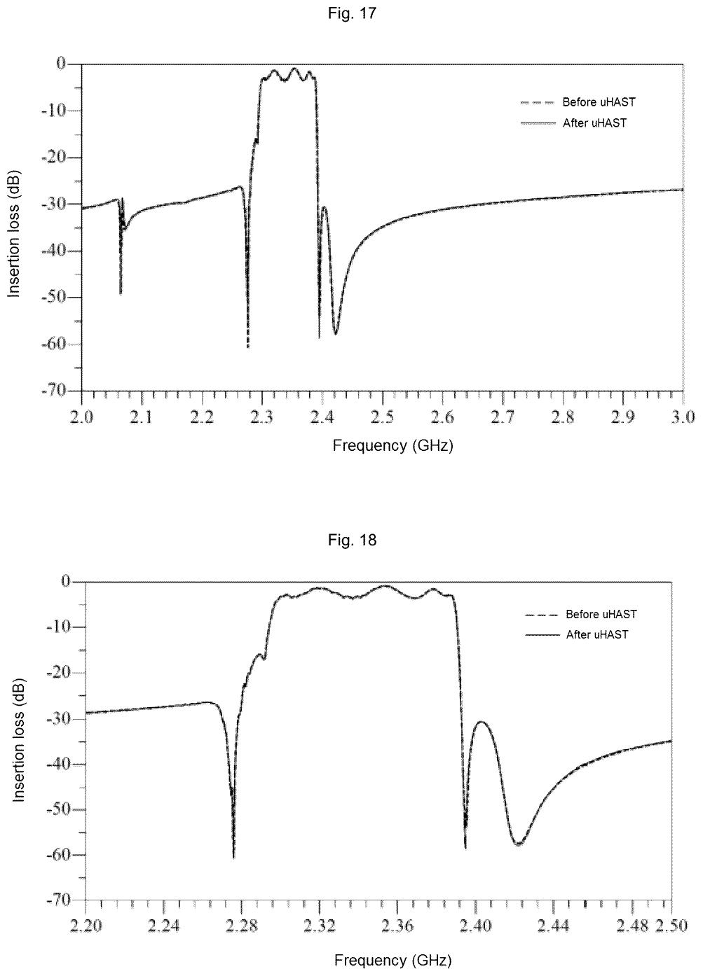

FIG. 17 is a response diagram of a test broad band of a ubias highly accelerated stress test on a bulk acoustic wave filter according to an embodiment of present application; and FIG. 18 is a response diagram of a test narrow band of a ubias highly accelerated stress test on a bulk acoustic wave filter according to an embodiment of present application. As shown in FIG. 17 and FIG. 18, Since the surfaces of the body sound wave filter in the present application are all covered with the protective layer, after the uHAST is carried out, the frequency of the filter basically does not shift, and the curves before and after the uHAST are basically consistent. According to FIG. 16, FIG. 17, and FIG. 18, it can be seen that the surface of each body sound wave resonator is covered with the protective layer, so that the body sound wave filter can be prevented from being interfered by water vapor, and the reliability of the body sound wave filter is improved.

It should be understood that processes in various forms shown above can be used for reordering, addition, or deletion of steps. For example, all the steps recorded in the present application can be executed in parallel, in sequence, or in different orders, as long as expected results of the technical solutions of the present application can be achieved, which will not be limited herein.

The above specific implementations do not impose a limitation on the protection scope of the present application. Those skilled in the art should understand that various modifications, combinations, sub-combinations, and substitutions can be made depending on the design requirements and other factors. Any modification, equivalent replacement, and improvement made within the spirit and scope of the present application shall fall within the protection scope of the present application.

What is claimed is:

1. A bulk acoustic wave resonator, comprising a substrate, a transducer stacking structure, and a protective layer, wherein the transducer stacking structure is located on one side of the substrate;
a cavity is arranged in the substrate, and the cavity penetrates through a portion of the substrate;
a release channel is arranged in the transducer stacking structure, and the release channel penetrates through the transducer stacking structure and is communicated to the cavity;
the protective layer is arranged on a surface of one side of the transducer stacking structure away from the substrate; and the protective layer comprises a waterproof material.

2. The bulk acoustic wave resonator as claimed in claim 1, wherein the bulk acoustic wave resonator further comprises a passivation layer;
the passivation layer is located between the protective layer and the transducer stacking structure, and the passivation layer covers the transducer stacking structure; and
a density of the protective layer is greater than a density of the passivation layer.

3. The bulk acoustic wave resonator as claimed in claim 1, wherein the protective layer is further arranged on an inner wall of the release channel and an inner wall of the cavity.

4. The bulk acoustic wave resonator as claimed in claim 1, wherein the protective layer comprises one or more of an inorganic oxide material, a metal oxide material, and a nitride material.

5. The bulk acoustic wave resonator as claimed in claim 1, wherein the transducer stacking structure comprises a bottom electrode layer, a piezoelectric layer, and a top electrode layer which are stacked;
the bulk acoustic wave resonator further comprises a first electrode plate and a second electrode plate;
the first electrode plate is connected to the piezoelectric layer and the bottom electrode layer through the protective layer; and the second electrode plate is connected to the top electrode layer through the protective layer.

6. The bulk acoustic wave resonator as claimed in claim 1, wherein the substrate comprises a bottom-layer substrate, a middle insulation layer, and a top-layer substrate; the top-layer substrate is located on one side close to the transducer stacking structure;
the cavity penetrates through the top-layer substrate;
the bulk acoustic wave resonator further comprises a protective wall;
the protective wall covers a side wall of the cavity; and the protective wall is located between the protective layer and the side wall of the cavity.

7. The bulk acoustic wave resonator as claimed in claim 1, wherein the bulk acoustic wave resonator further comprises a seed layer;
the seed layer is located between the substrate and transducer stacking structure; and the seed layer covers the substrate.

8. A preparation method of a bulk acoustic wave resonator, comprising:
providing a substrate;
growing a transducer stacking structure on one side of the substrate;
etching the transducer stacking structure to form a release channel, and introducing corrosive gas into the release channel to corrode the substrate and to form a cavity in the substrate; and
depositing a layer of protective layer on one side of the transducer stacking structure away from the substrate, so that the protective layer is arranged on a surface of the side of the transducer stacking structure away from the substrate,
wherein the protective layer comprises a waterproof material.

9. The preparation method as claimed in claim 8, wherein depositing the layer of protective layer on the one side of the transducer stacking structure away from the substrate comprises:
depositing the layer of protective layer on the side of the transducer stacking structure away from the substrate by using an atomic layer deposition technology.

10. The preparation method as claimed in claim 8, wherein growing the transducer stacking structure on the one side of the substrate comprises:
growing a bottom electrode layer and a piezoelectric layer in sequence on the one side of the substrate, and patterning the piezoelectric layer to form a groove that penetrates through the piezoelectric layer;
growing a top electrode layer on one side of the piezoelectric layer away from the substrate; and
growing an electrode plate layer on one side of the top electrode layer away from the substrate, and patterning the electrode plate layer to form a first electrode plate and a second electrode plate.

11. The preparation method as claimed in claim 10, wherein providing the substrate comprises:
etching the substrate in advance to form a third groove, wherein a range of the third groove is a range of the cavity; and
growing a sacrificial layer on one side of the substrate close to the third groove, and grinding the sacrificial layer to expose a surface of the substrate, so that the sacrificial layer only fills the third groove.

12. The preparation method as claimed in claim 11, wherein growing the bottom electrode layer and the piezoelectric layer in sequence on the one side of the substrate comprises:
growing a seed layer on one side of the substrate close to the sacrificial layer; and
growing the bottom electrode layer and the piezoelectric layer in sequence on one side of the seed layer away from the substrate.

13. The preparation method as claimed in claim 10, wherein growing the electrode plate layer on the one side of the top electrode layer away from the substrate comprises:
growing a passivation layer on one side of the top electrode layer away from the substrate, and patterning the passivation layer; and
growing the electrode plate layer on the one side of the top electrode layer away from the substrate comprises:
growing the electrode plate layer on one side of the passivation layer away from the substrate.

14. The preparation method as claimed in claim 10, further comprising:
etching one side of the substrate to form a positioning groove, wherein a region surrounded by the positioning groove is a range of the cavity; and
growing a protective wall in the positioning groove, and grinding the protective wall to expose a surface of the substrate, so that the protective wall fills the positioning groove.

15. The preparation method as claimed in claim 14, wherein growing the bottom electrode layer and the piezoelectric layer in sequence on the one side of the substrate comprises:
growing a seed layer on one side of the substrate close to the protective wall; and
growing the bottom electrode layer and the piezoelectric layer in sequence on one side of the seed layer away from the substrate.

16. The preparation method as claimed in claim 8, wherein the substrate comprises a bottom-layer substrate, a middle insulation layer, and a top-layer substrate which are stacked in sequence; the bottom-layer substrate is a silicon layer; and the top-layer substrate is a silicon nitride layer.

17. A bulk acoustic wave filter, comprising an input port, an output port, and a plurality of bulk acoustic wave resonators, wherein at least one of the bulk acoustic wave resonators is the bulk acoustic wave resonator as claimed in claim 1.
